(19) United States
(12) Patent Application Publication
(10) Pub. No.: US 2013/0149852 A1
(43) Pub. Date: Jun. 13, 2013

(54) METHOD FOR FORMING A SEMICONDUCTOR DEVICE

(71) Applicants: Genji Nakamura, Delmar, NY (US); Toshio Hasegawa, Delmar, NY (US)

(72) Inventors: Genji Nakamura, Delmar, NY (US); Toshio Hasegawa, Delmar, NY (US)

(73) Assignee: TOKYO ELECTRON LIMITED, Tokyo (JP)

(21) Appl. No.: 13/315,171

(22) Filed: Dec. 8, 2011

(51) Int. Cl. H01L 21/28

(52) U.S. Cl. 438/585; 257/E21.204

(57) ABSTRACT

A method for forming a semiconductor device includes providing in a process chamber a metal-containing gate electrode film on a substrate, flowing a process gas consisting of hydrogen (H₂) and optionally a noble gas into the process chamber, forming plasma excited species from the process gas by a microwave plasma source, and exposing the metal-containing gate electrode film to the plasma excited species to form a modified metal-containing gate electrode film having a lower work function than the metal-containing gate electrode film. Other embodiments describe forming semiconductor devices with gate stacks containing modified metal-containing gate electrodes for NMOS and PMOS transistors.

### FIELD OF THE INVENTION

The present invention relates to semiconductor processing, and more particularly to a method for plasma processing a metal-containing gate electrode film to adjust the work function of the metal-containing gate electrode film.

### BACKGROUND OF THE INVENTION

In the semiconductor industry, the minimum feature sizes of microelectronic devices are approaching the deep sub-micron regime to meet the demand for faster, lower power microprocessors and digital circuits. The Si-based microelectronic technology is currently faced with major materials challenges to achieve further miniaturization of integrated circuit devices. A gate stack containing a SiO₂ gate dielectric and a degenerately doped polycrystalline Si gate electrode, which has served the industry for several decades, will be replaced with a gate stack having a higher capacitance.

High-capacitance materials, known as high-k materials (where “k” refers to the dielectric constant of the material), feature a dielectric constant greater than that of SiO₂ (k˜3.9). In addition, high-k materials may refer to dielectric materials that are deposited onto substrates (e.g., HfO₂, ZrO₂) rather than grown on the surface of the substrates (e.g., SiO₂, SiOₓN_{y}). High-k materials may, for example, incorporate metallic silicates or oxides (e.g., Ta₂O₅ (k˜26), TiO₂ (k˜80), ZrO₂ (k˜25), Al₂O₃ (k˜9), HfSiO (k˜5-25), and HfO₂ (k˜25)).

In addition to the gate dielectric layer, the gate electrode layer also represents a major challenge for future scaling of microelectronic devices. The introduction of metal-containing gate electrodes to replace the traditional doped poly-Si gate electrode can bring about several advantages. These advantages include elimination of the poly-Si gate depletion effect, reduction in sheet resistance, better reliability and potentially better thermal stability on the advanced high-k dielectric materials. In one example, switching from poly-Si to a metal-containing gate electrode can achieve a 2-3 Angstrom (Å) improvement in the effective or electrical thickness of the gate stack. This improvement occurs largely because the problem of poly-Si depletion at the interfaces with other materials is removed entirely.

Work function, resistivity, and compatibility with complementary metal oxide semiconductor (CMOS) technology are key parameters for the new gate electrode materials. One of the material selection criteria for the metal-containing gate electrode is that the work function be tunable. The work function of a material is the minimum energy needed to remove an electron from a solid to a point immediately outside the solid surface. Positive-channel Metal Oxide Semiconductor (PMOS) and the Negative-channel Metal Oxide Semiconductor (NMOS) transistor gate electrodes require different gate materials be used for the gate electrode to achieve acceptable threshold voltages; the latter having a Fermi level near the silicon valence band (E˜4 eV), and the former having a Fermi level near the conduction band (E˜5.1 eV).

High-energy implantation of dopant ions (e.g., nitrogen ions) into a metal gate electrode layer in a gate stack has been previously researched in order to lower the work function. However, ion implantation methods that include exposing the metal layer to high-energy ions can damage the gate stack, for example cause charging damage of the dielectric layer that can increase the leakage current and the reliability of the dielectric layer. The charging damage from exposure of high-energy ions is expected to increase as the minimum feature sizes get smaller and the different materials layers that form gate stacks get thinner. Therefore, new methods are needed for processing gate stacks and, in particular, new methods for tuning the work function of the gate stacks are needed.

### SUMMARY OF THE INVENTION

Embodiments of the invention provide a method for manufacturing a semiconductor device containing a metal-containing gate electrode film with a tunable work function.

According to one embodiment of the invention, the method includes providing in a process chamber a metal-containing gate electrode film on a substrate, flowing a process gas consisting of hydrogen (H₂) and optionally a noble gas into the process chamber, forming plasma excited species from the process gas by a microwave plasma source, and exposing the metal-containing gate electrode film to the plasma excited species to form a modified metal-containing gate electrode film having a lower work function than the metal-containing gate electrode film.

According to another embodiment, the method includes providing in a process chamber a metal-containing gate electrode film on a substrate, forming first plasma excited species from a first process gas by a microwave plasma source, and exposing the metal-containing gate electrode film to the first plasma excited species to form a first modified metal-containing gate electrode film and an unmodified metal-containing gate electrode film. The method can further include forming second plasma excited species from a second process gas by the microwave plasma source, and exposing the unmodified metal-containing gate electrode film to the second plasma excited species to form a second modified metal-containing gate electrode film.

### BRIEF DESCRIPTION OF THE DRAWINGS

In the drawings:

FIGS. 1A-1D schematically show cross-sectional views of a method of forming a gate stack containing a modified metal-containing gate electrode according to an embodiment of the invention;

FIG. 2 is a flow diagram for a method of forming a film structure containing a modified metal-containing gate electrode according to an embodiment of the invention;

FIGS. 3A-3E schematically show cross-sectional views of a method of forming a gate stack containing a modified metal-containing gate electrode according to an embodiment of the invention;

FIG. 4 is a flow diagram for a method of forming a gate stack containing a modified metal-containing gate electrode according to an embodiment of the invention;

FIGS. 5A-5E schematically show cross-sectional views of a method of forming gate stacks containing modified metal-containing gate electrodes according to an embodiment of the invention;

FIG. 6 is a flow diagram for a method of forming gate stacks containing modified metal-containing gate electrodes according to an embodiment of the invention;

FIG. 7A shows flat band voltage (V_{fb}) as a function of equivalent oxide thickness (EOT) for modified titanium nitride (TiN) gate electrode films;

FIG. 7B shows leakage current (J_{g}) as a function of equivalent oxide thickness (EOT) for modified titanium nitride (TiN) gate electrode films;

FIG. 8 is a schematic diagram of a plasma processing system containing a radial line slot antenna (RLSA) microwave plasma source for modifying a metal-containing gate electrode film according to an embodiment of the invention;

FIG. 9 is a schematic diagram of a another plasma processing system containing a radial line slot antenna (RLSA) microwave plasma source for modifying a metal-containing gate electrode film according to an embodiment of the invention;

FIG. 10 illustrates a plan view of a gas supplying unit of the plasma processing system in FIG. 9; and

FIG. 11 illustrates a partial cross-sectional view of an antenna portion of the plasma processing system in FIG. 9.

### DETAILED DESCRIPTION OF SEVERAL EMBODIMENTS OF THE INVENTION

In the following description, in order to facilitate a thorough understanding of the invention and for purposes of explanation and not limitation, specific details are set forth, such as a particular geometry of a plasma processing system and descriptions of various components. However, it should be understood that the invention may be practiced in other embodiments that depart from these specific details.

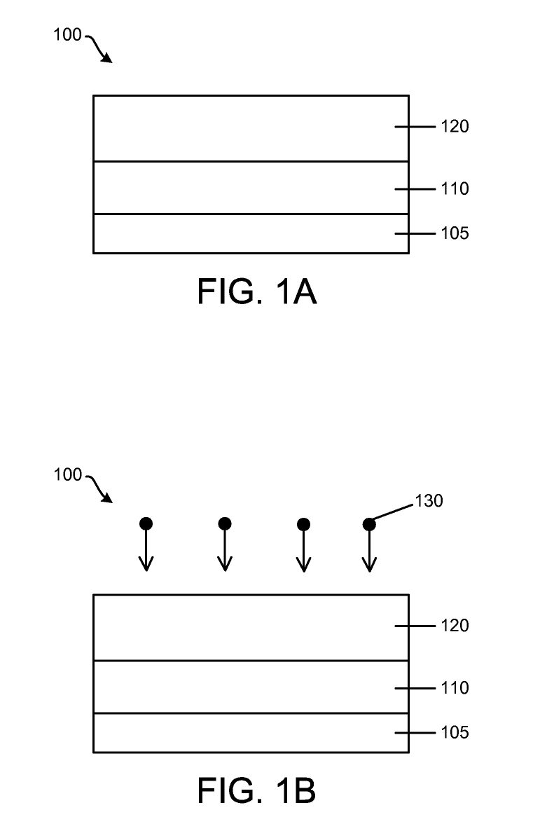

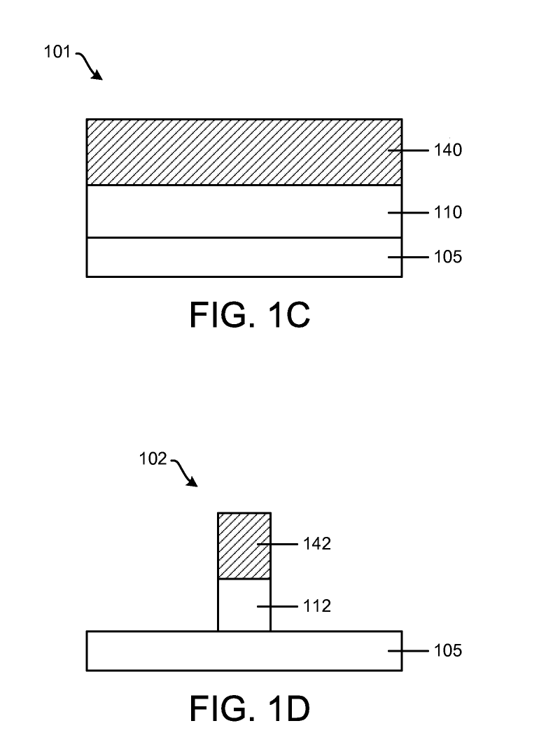

FIGS. 1A-1D schematically show cross-sectional views of a method of forming a gate stack containing a modified metal-containing gate electrode according to an embodiment of the invention. FIG. 1A schematically shows a cross-sectional view of a film stack 100 containing a substrate 105, a dielectric layer 110 on the substrate 105, and a metal-containing gate electrode film 120 on the dielectric layer 110. The substrate 105 can, for example, contain Si, Ge, SiGe, or GaAs. In addition, the substrate 105 can contain a silicon-on-insulator (SOI) material. The insulator can, for example, be SiO₂. A Si substrate can be of n- or p-type, depending on the type of device being formed. The substrate (wafer) 105 can be of any size, for example a 200 mm wafer, a 300 mm wafer, a 450 mm wafer, or an even larger wafer.

The dielectric layer 110 can contain a SiO₂ (or SiOₓ) layer, a SiN (or SiN_{y}) layer, a SiON (or SiOₓN_{y}) layer, or a high-k layer, or a combination of two or more thereof. The high-k layer can, for example, contain metal oxides and their silicates, including Ta₂O₅, TiO₂, ZrO₂, Al₂O₃, Y₂O₃, HfSiOₓ, HfO₂, ZrO₂, ZrSiOₓ, TaSiOₓ, SrOₓ, SrSiOₓ, LaOₓ, LaSiOₓ, YOₓ, or YSiOₓ, or combinations of two or more thereof. A thickness of the high-k layer can, for example, be between about 10 angstrom (Å) and about 200 Å or between about 20 Å and about 40 Å. In one example, the dielectric layer 110 can contain an interface layer (not shown) in direct contact with the substrate 105, for example an oxide layer (e.g., SiOₓ), a nitride layer (e.g., SiNₓ), or an oxynitride layer (e.g., SiOₓN_{y}), or a combination thereof. Integrated circuits containing a Si substrate commonly employ SiO₂ and/or SiOₓN_{y} substrate interface layers that can have excellent electrical properties, including high electron mobility and low electron trap densities. Gate stacks containing a high-k layer formed on SiO₂ and/or SiOₓN_{y} substrate interface layers can require the substrate interface layer to have a thickness of only about 5-10 Å.

The metal-containing gate electrode film 120 can include metals and metal-containing materials, including W, WN, Al, Mo, Ta, TaN, TaSiN, HfN, HfSiN, Ti, TiN, TiSiN, Mo, MoN, Nb, Re, Ru, or RuO₂. A thickness of the metal-containing gate electrode film 120 can, for example, be between about 10 Å and about 500 Å or between about 20 Å and about 200 Å.

FIG. 1B schematically shows a process of exposing the metal-containing gate electrode film 120 to plasma excited species 130. The exposure to the plasma excited species 130 lowers the work function of the metal-containing gate electrode film 120. According to one embodiment of the invention, a process gas consisting of hydrogen (H₂) and optionally a noble gas is flowed into a process chamber, and the plasma excited species 130 may be characterized as reducing species formed from the process gas in the process chamber by a microwave plasma source.

FIG. 1C schematically shows a cross-sectional view of a film stack 101 containing a modified metal-containing gate electrode film 140 following the exposure of the metal-containing gate electrode film 120 to the plasma excited species 130. The modified metal-containing gate electrode film 140 has a lower work function than the metal-containing gate electrode film 130. According to one embodiment, the modified metal-containing gate electrode film 140 may be used as a NMOS gate electrode in a semiconductor device.

FIG. 1D schematically shows a cross-sectional view of a gate stack 102 containing a metal-containing gate electrode 142 on a gate dielectric 112. The gate stack 102 may, for example, be formed by applying lithographic methods and dry etching techniques to anisotropically etch the film stack 101 shown in FIG. 1C.

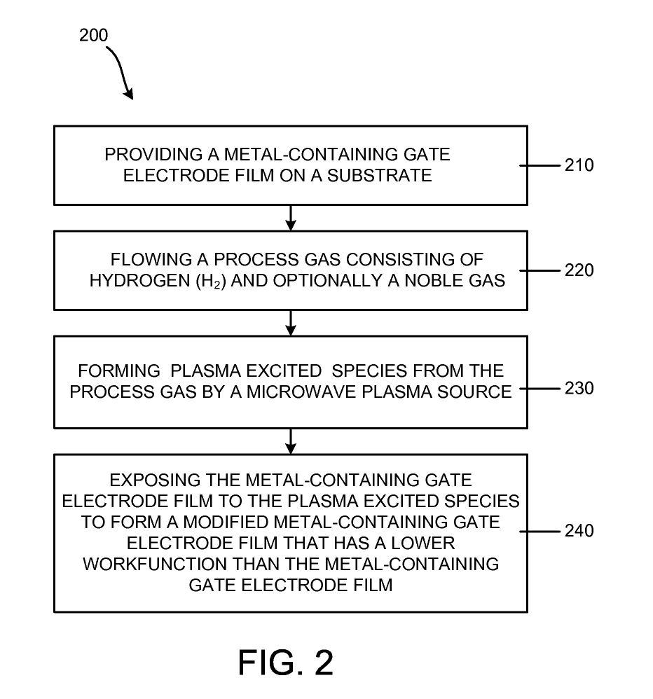

FIG. 2 is a flow diagram for a method of forming a film structure containing a modified metal-containing gate electrode film according to an embodiment of the invention. Referring also to FIGS. 1A-1D, process 200 includes, in 210, providing in a process chamber of a plasma processing system a film stack 100 containing a metal-containing gate electrode film 120 on a substrate 105. In the exemplary embodiment shown in FIG. 1A, the film stack 100 further contains a dielectric layer 110 between the substrate 105 and the metal-containing gate electrode film 120.

In 220, a process gas consisting of hydrogen (H₂) and optionally a noble gas is flowed into the process chamber. In one example, the process gas can consist of H₂. In another example, the process gas can consist of H₂ and Argon (Ar). In yet another example, the process gas can consist of H₂ and Helium (He). In still another example, the process gas can consist of H₂, Ar, and He.

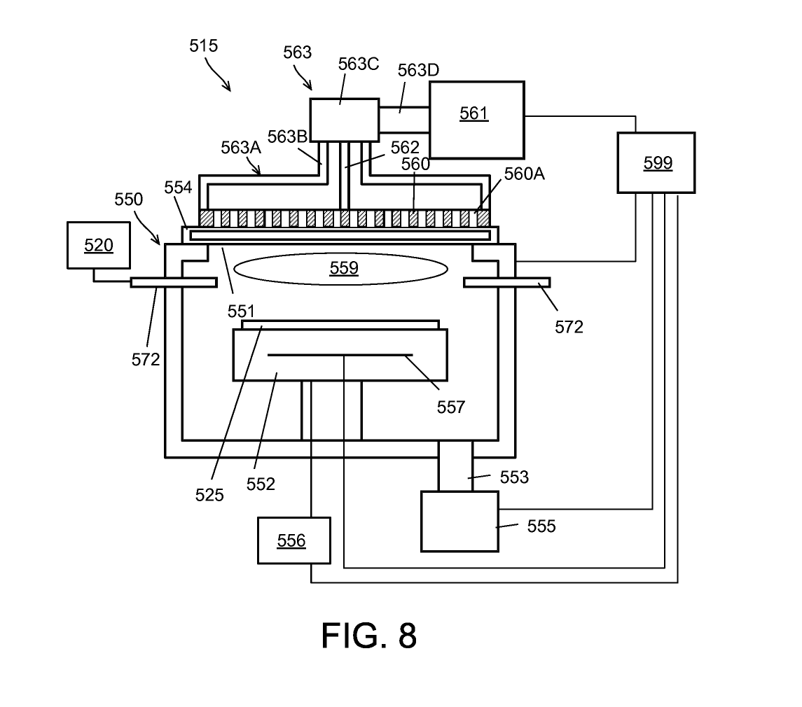

In 230, plasma excited species 130 are formed from the process gas by a microwave plasma source. According to one embodiment, the microwave plasma source can be a radial line slot antenna (RLSA) plasma source available from Tokyo Electron Limited, Akasaka, Japan. Exemplary microwave plasma sources are shown in FIGS. 8-11.

In 240, the metal-containing gate electrode film 120 is exposed to the plasma excited species 130 to form a modified metal-containing gate electrode film 140 that has a lower work function than the metal-containing gate electrode film 120. The plasma excited species may include reducing species with low kinetic energy that can selectively modify the metal-containing gate electrode film 120 (or only a surface layer of the metal-containing gate electrode film 120), while minimizing or eliminating charging damage in underlying films or layers. The modification of the metal-containing gate electrode film 120 may be substantially uniform through a thickness of the modified metal-containing gate electrode film 140, or alternately, the modification of the metal-containing gate electrode film 120 may be substantially non-uniform through a thickness of the modified metal-containing gate electrode film 140.

The exposure of the metal-containing gate electrode 120 to the plasma excited species 130 in 240 may be performed using processing parameters that result in a desired modification of the metal-containing gate electrode film 120. Process parameters for the exposure can be determined by direct experimentation and/or design of experiments (DOE). As one skilled in the art will readily appreciate, adjustable process parameters include, among others, plasma conditions (plasma power, process pressure, and process gas composition), process time, and substrate temperature.

The process 200 may further contain an annealing step for heat-treating one or more of the film stacks 100 and 101, and/or or the gate stack 102 following the exposure to the plasma excited species 130. The heat-treating can be performed to obtain the desired work function and material and electrical properties of the film stacks 100 and 101, and/or the gate stack 102. As would be appreciated by those skilled in the art, each of the steps or stages in the flowchart of FIG. 2 may encompass one or more separate steps and/or operations. Accordingly, the recitation of only four steps in 210, 220, 230, and 240 should not be understood to limit the method of the present invention solely to four steps or stages. Moreover, each representative step or stage 210, 220, 230, and 240 should not be understood to be limited to only a single process.

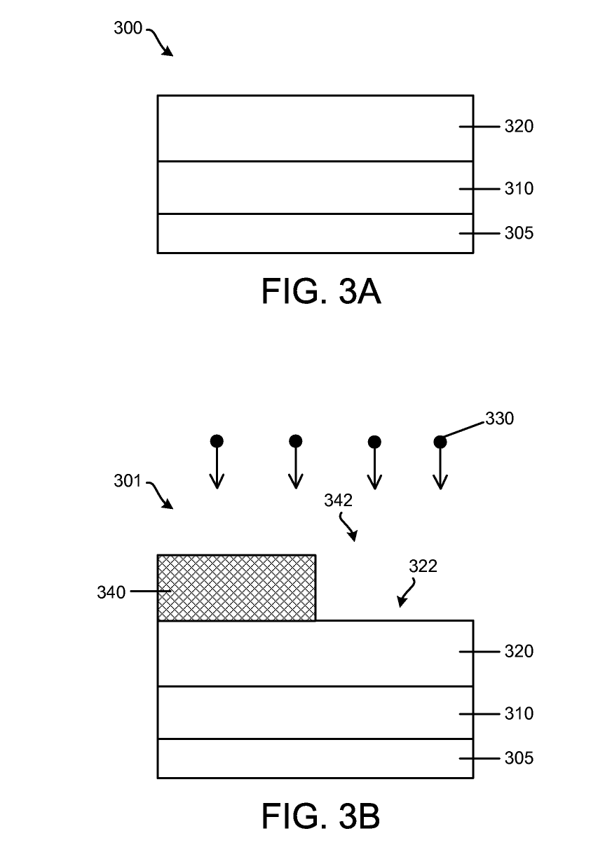

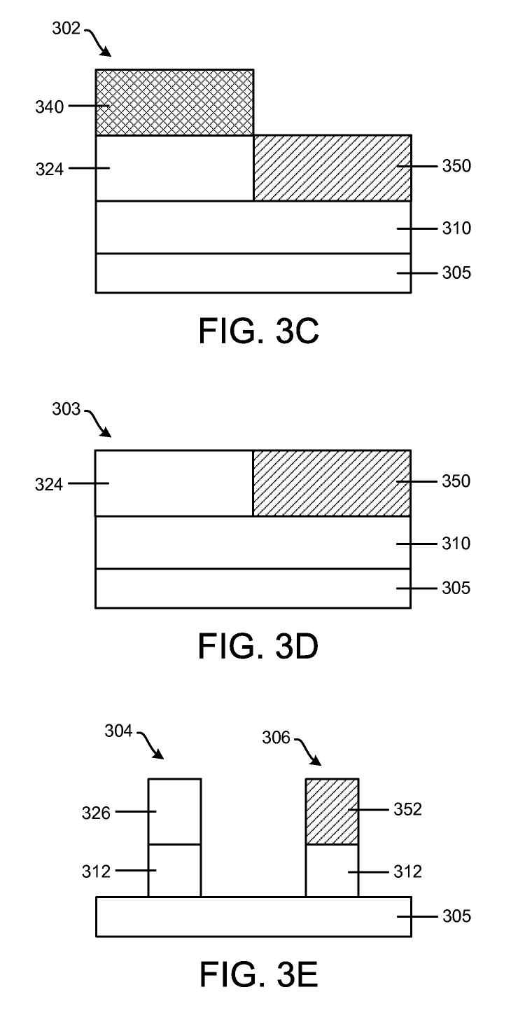

FIGS. 3A-3E schematically show cross-sectional views of a method of forming a gate stack containing a modified metal-containing gate electrode according to an embodiment of the invention. FIG. 3A schematically shows a cross-sectional view of a film stack 300 containing a substrate 305, a dielectric layer 310 on the substrate 305, and a metal-containing gate electrode film 320 on the dielectric layer 310. The substrate 305 can, for example, contain Si, Ge, SiGe, or GaAs. In addition, the substrate 305 can contain a silicon-on-insulator (SOI) material. The insulator can, for example, be SiO₂. A Si substrate can be of n- or p-type, depending on the type of device being formed. The substrate (wafer) 305 can be of any size, for example a 200 mm wafer, a 300 mm wafer, a 450 mm wafer, or an even larger wafer.

The dielectric layer 310 can contain a SiO₂ (or SiOₓ) layer, a SiN (or SiN_{y}) layer, a SiON (or SiOₓN_{y}) layer, or a high-k layer, or a combination of two or more thereof. The high-k layer can, for example, contain metal oxides and their silicates, including Ta₂O₅, TiO₂, ZrO₂, Al₂O₃, Y₂O₃, HfSiOₓ, HfO₂, ZrO₂, ZrSiOₓ, TaSiOₓ, SrOₓ, SrSiOₓ, LaOₓ, LaSiOₓ, YOₓ, or YSiOₓ, or combinations of two or more thereof. A thickness of the high-k layer can, for example, be between about 10 angstrom (Å) and about 200 Å or between about 20 Å and about 40 Å. In one example, the dielectric layer 310 can contain an interface layer (not shown) in direct contact with the substrate 305, for example an oxide layer (e.g., SiOₓ), a nitride layer (e.g., SiNₓ), or an oxynitride layer (e.g., SiOₓN_{y}), or a combination thereof. Integrated circuits containing a Si substrate commonly employ SiO₂ and/or SiOₓN_{y} substrate interface layers that can have excellent electrical properties, including high electron mobility and low electron trap densities. Gate stacks containing a high-k layer formed on SiO₂ and/or SiOₓN_{y} substrate interface layers can require the substrate interface layer to have a thickness of only about 5-10 Å.

The metal-containing gate electrode film 320 can include metals and metal-containing materials, including W, WN, Al, Mo, Ta, TaN, TaSiN, HfN, HfSiN, Ti, TiN, TiSiN, Mo, MoN, Re, or Ru. A thickness of the metal-containing gate electrode film 320 can, for example, be between about 10 Å and about 500 Å or between about 20 Å and about 200 Å.

FIG. 3B schematically shows a cross-sectional view of a film stack 301 containing a patterned film 340 formed on the metal-containing gate electrode film 320. The patterned film 340 may contain a photoresist film and/or a hard mask that is formed by patterning a blanket photoresist film and/or a blanket hard mask using well known lithographic techniques and anisotropic etching methods. The patterned film 340 contains an opening 342 for exposing a first portion 322 of the metal-containing gate electrode film 320 to first plasma excited species 330. According to one embodiment of the invention, a process gas consisting of hydrogen (H₂) and optionally a noble gas is flowed into a process chamber, and the first plasma excited species 330 may be characterized as reducing species that are formed from the process gas in the process chamber by a microwave plasma source. According to another embodiment of the invention, a process gas consisting of oxygen (O₂) and optionally one or more gases selected from the group consisting of a noble gas, nitrogen (N₂), H₂, or a combination thereof, is flowed into a process chamber, and the first plasma excited species 330 may be characterized as oxidizing species that are formed from the process gas in the process chamber by a microwave plasma source.

FIG. 3C schematically shows a cross-sectional view of a film stack 302 containing a first modified metal-containing gate electrode film 350 and an unmodified metal-containing gate electrode film 324 underneath the patterned film 340. According to one embodiment, the first plasma excited species 330 may be characterized as reducing species and the first modified metal-containing gate electrode film 350 has a lower work function than the unmodified metal-containing gate electrode film 324. According to another embodiment, the first plasma excited species 330 may be characterized as oxidizing species and the first modified metal-containing gate electrode film 350 has a higher work function than the unmodified metal-containing gate electrode film 324.

FIG. 3D schematically shows a cross-sectional view of a film stack 303 following removal of the patterned film 340 from the film stack 302 in FIG. 3C. The patterned film 340 may be removed using conventional wet or dry etching methods.

According to some embodiments of the invention, the film stack 303 may be further processed in the manufacturing of a semiconductor device. FIG. 3E schematically shows a cross-sectional view a first gate stack 306 containing a first metal-containing gate electrode 352 on gate dielectric 312 and a second gate stack 304 containing a second metal-containing gate electrode 326 on gate dielectric 312. According to one embodiment, the first modified metal-containing gate electrode film 350 has a lower work function than the unmodified metal-containing gate electrode film 324 and the first gate stack 306, containing gate electrode 352, has a lower work function than the second gate stack 304, containing gate electrode 326. In this embodiment, the gate electrode 352 can be a NMOS gate electrode and the gate electrode 326 can be a PMOS gate electrode. According to another embodiment, the first modified metal-containing gate electrode film 350 has a higher work function than the unmodified metal-containing gate electrode film 324 and the first gate stack 306, containing gate electrode 352, has a higher work function than the second gate stack 304, containing gate electrode 326. In this embodiment, the gate electrode 352 can be a PMOS gate electrode and the gate electrode 326 can be a NMOS gate electrode. Thus, a single metal or metal-containing gate electrode film 320 may be modified to form a dual-work function metal gate NMOS and PMOS. The first gate stack 306 and the second gate stack 304 may, for example, be formed by anisotropic etching of the film stack 303 shown in FIG. 3D using lithographic methods and dry etching techniques.

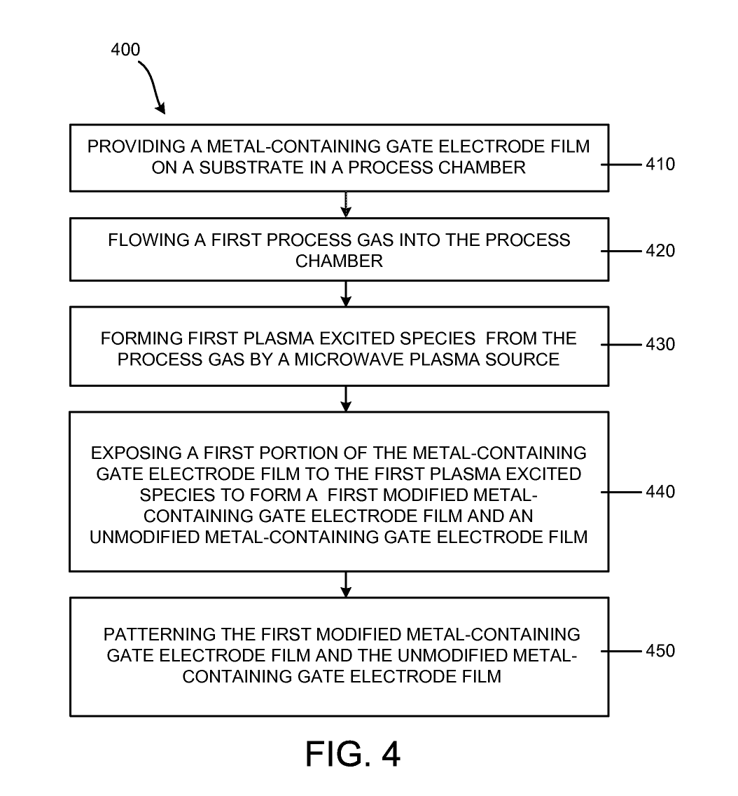

FIG. 4 is a flow diagram for a method of forming a gate stack containing a modified metal-containing gate electrode according to an embodiment of the invention. Referring also to FIGS. 3A-3E, process 400 includes, in 410, providing in a process chamber of a plasma processing system a film stack 300 containing a metal-containing gate electrode film 320 on a substrate 305. In the exemplary embodiment shown in FIG. 3A, the film stack 300 further contains a dielectric layer 310 between the substrate 305 and the metal-containing gate electrode film 320.

In 420, a first process gas is flowed into the process chamber. According to one embodiment of the invention, the first process gas can consist of hydrogen (H₂) and optionally a noble gas. In one example, the first process gas can consist of H₂. In another example, the first process gas can consist of H₂ and Ar. In yet another example, the process gas can consist of H₂ and He. In still another example, the first process gas can consist of H₂, Ar, and He. According to another embodiment of the invention, the first process gas can consist of oxygen (O₂) and optionally one or more gases selected from the group consisting of a noble gas, nitrogen (N₂), H₂, or a combination thereof. In one example, the first process gas can consist of O₂. In another example, the first process gas can consist of O₂ and Ar. In yet another example, the first process gas can consist of O₂, N₂, and optionally Ar. In still another example, the first process gas can consist of O₂, Ar, and He.

In 430, first plasma excited species 330 are formed from the first process gas by a microwave plasma source. According to one embodiment of the invention, the first plasma excited species 330 may include reducing species formed by plasma excitation of the first process gas consisting of hydrogen (H₂) and optionally a noble gas. According to another embodiment of the invention, the first plasma excited species may include oxidizing species formed by plasma excitation of a first process gas consisting of oxygen (O₂) and optionally one or more gases selected from the group consisting of a noble gas, N₂, H₂, or a combination thereof. According to one embodiment, the microwave plasma source can be a radial line slot antenna (RLSA) plasma source available from Tokyo Electron Limited, Akasaka, Japan.

In 440, a first portion 322 of the metal-containing gate electrode film 320 is exposed to the first plasma excited species 330 to form a first modified metal-containing gate electrode film 350 and an unmodified metal-containing gate electrode film 324. In one embodiment, the first plasma excited species 330 may include reducing species and the first modified metal-containing gate electrode film 350 has a lower work function than the unmodified metal-containing gate electrode film 324. In another embodiment, the first plasma excited species 330 may include oxidizing species and the first modified metal-containing gate electrode film 350 has a higher work function than the unmodified metal-containing gate electrode film 324.

The exposure of the metal-containing gate electrode film 320 to the first plasma excited species 330 in 440 may be performed under processing parameters for a time period that result in a desired modification of the metal-containing gate electrode film 320. Process parameters for the exposure can be determined by direct experimentation and/or design of experiments (DOE). As one skilled in the art will readily appreciate, adjustable process parameters include, among others, plasma conditions (plasma power, process pressure, and process gas composition), process time, and substrate temperature.

Following the exposure to the first plasma excited species 330 in 440, the patterned film 340 may be removed using conventional wet or dry etching methods.

In 450, the film stack 303 may, as depicted in FIG. 3E, be further processed by patterning the first modified metal-containing gate electrode film 350, the unmodified metal-containing gate electrode film 324, and the underlying dielectric film 310 to form a first gate stack 306 and a second gate stack 304. According to one embodiment, the first gate stack 306 has a lower work function than the second gate stack 304. According to another embodiment, the first gate stack 306 has a higher work function than the second gate stack 304. The first gate stack 306 and the second gate stack 304 may, for example, be formed by anisotropic etching of the film stack 303 shown in FIG. 3D using lithographic methods and dry etching techniques.

The process 400 may further contain an annealing step for heat-treating one or more of the film stacks 301, 301 and 302, and/or or the gate stacks 304/306 following the exposure to the first plasma excited species 330. The heat-treating can be performed to obtain the desired work function and material and electrical properties of the gate stacks 304/306. As would be appreciated by those skilled in the art, each of the steps or stages in the flowchart of FIG. 4 may encompass one or more separate steps and/or operations. Accordingly, the recitation of only five steps in 410, 420, 430, 440, and 450 should not be understood to limit the method of the present invention solely to five steps or stages. Moreover, each representative step or stage 410, 420, 430, 440, and 450 should not be understood to be limited to only a single process.

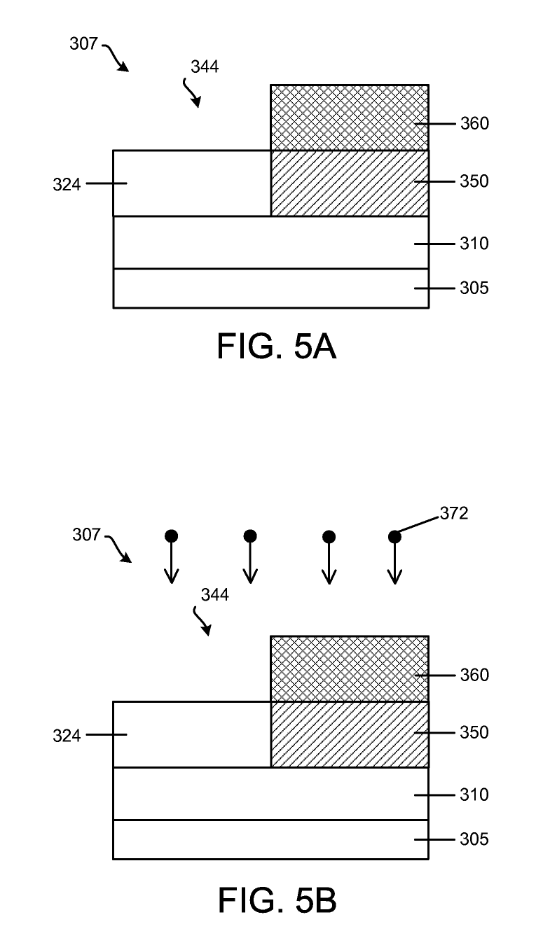

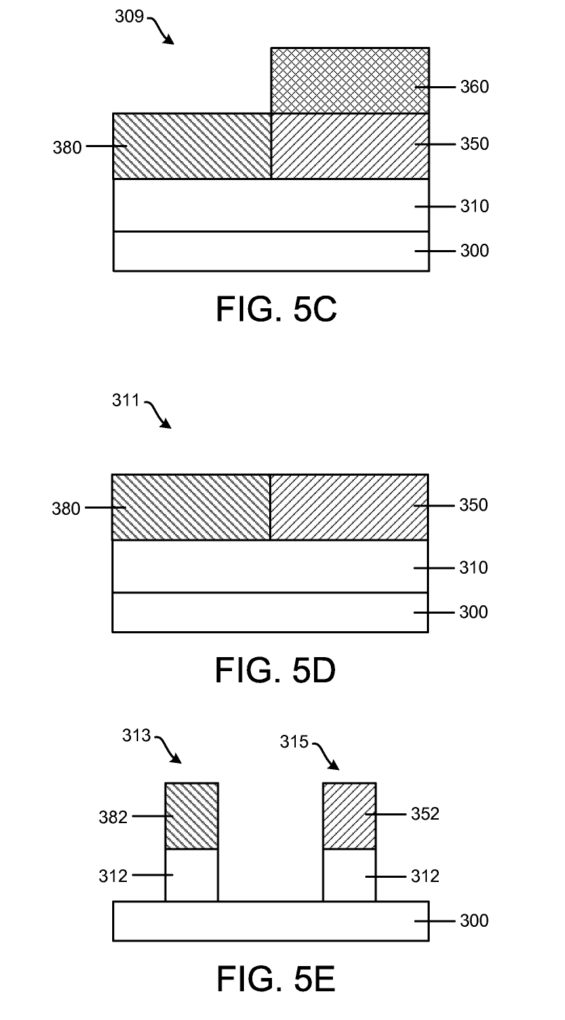

FIGS. 5A-5E schematically show cross-sectional views of a method of forming gate stacks containing modified metal-containing gate electrodes according to an embodiment of the invention. FIG. 5A schematically shows a cross-sectional view of a film stack 307 containing a patterned film 360 formed on the first modified metal-containing gate electrode film 350 of the film stack 303 shown in FIG. 3D. The patterned film 360 may contain a photoresist film and/or a hard mask that is formed by patterning a blanket photoresist film and/or a blanket hard mask using well known lithographic techniques and anisotropic etching methods. The patterned film 360 contains an opening 344 for exposing the unmodified metal-containing gate electrode film 324.

FIG. 5B schematically shows a process for exposing a film stack 307 containing the unmodified metal-containing gate electrode film 324 to second plasma excited species 372. According to one embodiment of the invention, a second process gas consisting of oxygen (O₂) and optionally one or more gases selected from the group consisting of a noble gas, nitrogen (N₂), H₂, or a combination thereof, is flowed into a process chamber, and the second plasma excited species 372 may be characterized as oxidizing species that are formed from the second process gas in the process chamber by a microwave plasma source. According to another embodiment of the invention, a second process gas consisting of hydrogen (H₂) and optionally a noble gas is flowed into a process chamber, and the second plasma excited species 372 may be characterized as reducing species that are formed from the second process gas in the process chamber by a microwave plasma source.

FIG. 5C schematically shows a cross-sectional view of a film stack 309 containing a second modified metal-containing gate electrode film 380 and first modified metal-containing gate electrode film 350 underneath the patterned film 360. According to one embodiment, the second plasma excited species 372 may include oxidizing species and second modified metal-containing gate electrode film 380 has a higher work function than the first modified metal-containing gate electrode film 350. According to another embodiment, the second plasma excited species 372 may include reducing species and the second modified metal-containing gate electrode film 380 has a lower work function than the first modified metal-containing gate electrode film 350.

FIG. 5D schematically shows a cross-sectional view of a film stack 311 following removal of the patterned film 360 from the film stack 309 in FIG. 5C. The patterned film 360 may be removed using conventional wet or dry etching methods.

According to some embodiments of the invention, the film stack 311 may be further processed in the manufacturing of a semiconductor device. FIG. 5E schematically shows a cross-sectional view a first gate stack 315 containing a first metal-containing gate electrode 352 on gate dielectric 312 and a second gate stack 313 containing a second metal-containing gate electrode 382 on gate dielectric 312. According to one embodiment, the first gate stack 315, containing gate electrode 352, has a lower work function than the second gate stack 313, containing gate electrode 382. In this embodiment, the gate electrode 352 can be a NMOS gate electrode and the gate electrode 382 can be a PMOS gate electrode. According to another embodiment, the first gate stack 315, containing gate electrode 352, has a higher work function than the second gate stack 313, containing gate electrode 382. In this embodiment, the gate electrode 352 can be a PMOS gate electrode and the gate electrode 382 can be a NMOS gate electrode. The first gate stack 315 and the second gate stack 313 may, for example, be formed by anisotropic etching of the film stack 311 shown in FIG. 5D using lithographic methods and dry etching techniques.

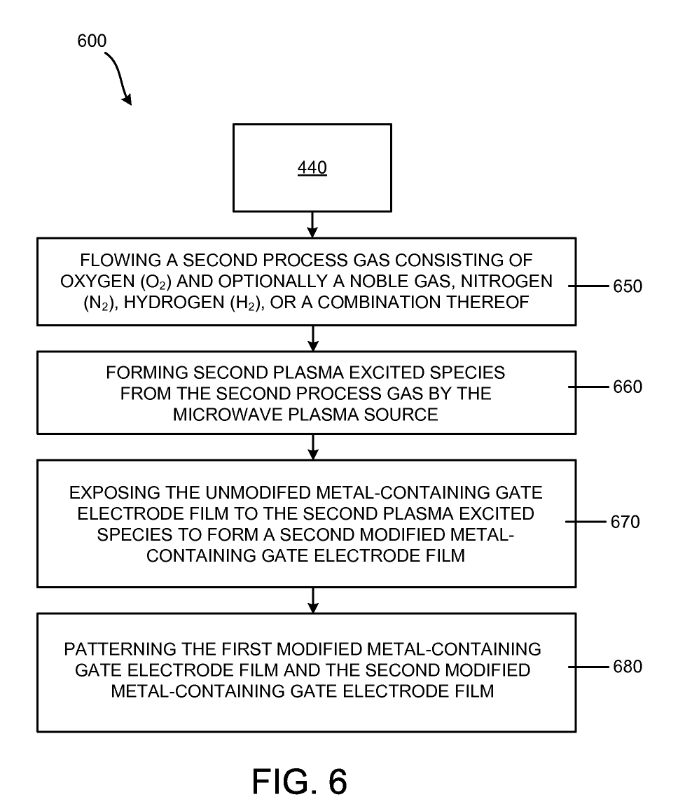

FIG. 6 is a flow diagram for a method of forming gate stacks containing modified metal-containing gate electrodes according to an embodiment of the invention. Referring also to FIGS. 5A-5E, process 600 includes steps 410-440 of process 400 in FIG. 4.

In 650, a second process gas is flowed into the process chamber. According to one embodiment of the invention, the second process gas can consist of oxygen (O₂) and optionally one or more gases selected from the group consisting of a noble gas, nitrogen (N₂), H₂, or a combination thereof. In one example, the second process gas can consist of O₂. In another example, the second process gas can consist of O₂ and Ar. In yet another example, the second process gas can consist of O₂, N₂, and optionally Ar. In still another example, the second process gas can consist of O₂, Ar, and He. According to another embodiment, the second process gas can consist of hydrogen H₂ and optionally a noble gas. In one example, the second process gas can consist of H₂. In another example, the second process gas can consist of H₂ and Ar. In yet another example, the second process gas can consist of H₂ and He. In still another example, the second process gas can consist of H₂, Ar, and He.

In 660, second plasma excited species 672 are formed from the second process gas by a microwave plasma source. According to one embodiment, the second plasma excited species 672 may include oxidizing species formed by plasma excitation of a second process gas consisting of oxygen (O₂) and optionally one or more gases selected from the group consisting of a noble gas, N₂, H₂, or a combination thereof. According to another embodiment, the second plasma excited species 672 may include reducing species formed by plasma excitation of the second process gas consisting of hydrogen (H₂) and optionally a noble gas. According to one embodiment, the microwave plasma source can be a radial line slot antenna (RLSA) plasma source available from Tokyo Electron Limited, Akasaka, Japan.

In 670, the film stack 307 containing the unmodified metal-containing gate electrode film 324 is exposed to second plasma excited species 372 to form a second modified metal-containing gate electrode film 380. In one embodiment, the second plasma excited species 372 may include oxidizing species and the second modified metal-containing gate electrode film 380 has a higher work function than the first modified metal-containing gate electrode film 350. In another embodiment, the second plasma excited species 372 may include reducing species and the first modified metal-containing gate electrode film 350 has a higher work function than the first modified metal-containing gate electrode film 350.

The exposure of the unmodified metal-containing gate electrode film 324 to the second plasma excited species 372 in 670 may be performed under processing parameters that result in a desired modification of the unmodified metal-containing gate electrode film 324. Process parameters for the exposure can be determined by direct experimentation and/or design of experiments (DOE). As one skilled in the art will readily appreciate, adjustable process parameters include, among others, plasma conditions (plasma power, process pressure, and process gas composition), process time, and substrate temperature.

Following the exposure to the second plasma excited species 372 in 670, the patterned film 360 may be removed using conventional wet or dry etching methods.

In 680, the resulting film stack 311 may be further processed by patterning the first modified metal-containing gate electrode film 350, the second modified metal-containing gate electrode film 380 and the underlying dielectric film 310 to form a first gate stack 315 and a second gate stack 313. According to one embodiment, the first gate stack 315, containing gate electrode 352, has a lower work function than the second gate stack 313, containing gate electrode 382. In this embodiment, the gate electrode 352 can be a NMOS gate electrode and the gate electrode 382 can be a PMOS gate electrode. According to another embodiment, the first gate stack 315, containing gate electrode 352, has a higher work function than the second gate stack 313, containing gate electrode 382. In this embodiment, the gate electrode 352 can be a PMOS gate electrode and the gate electrode 382 can be a NMOS gate electrode. The first gate stack 315 and the second gate stack 313 may, for example, be formed by anisotropic etching of the film stack 311 shown in FIG. 5D using lithographic methods and dry etching techniques.

The process 600 may further contain an annealing step for heat-treating one or more of the film stacks 307, 309 and 311, and/or or the gate stacks 313/315 following the exposure to the second plasma excited species 372. The heat-treating can be performed to obtain the desired work function and material and electrical properties of the gate stacks 313/315. As would be appreciated by those skilled in the art, each of the steps or stages in the flowchart of FIG. 6 may encompass one or more separate steps and/or operations. Accordingly, the recitation of only four steps in 650, 660, 670, and 680 should not be understood to limit the method of the present invention solely to four steps or stages. Moreover, each representative step or stage 650, 660, 670, and 680 should not be understood to be limited to only a single process.

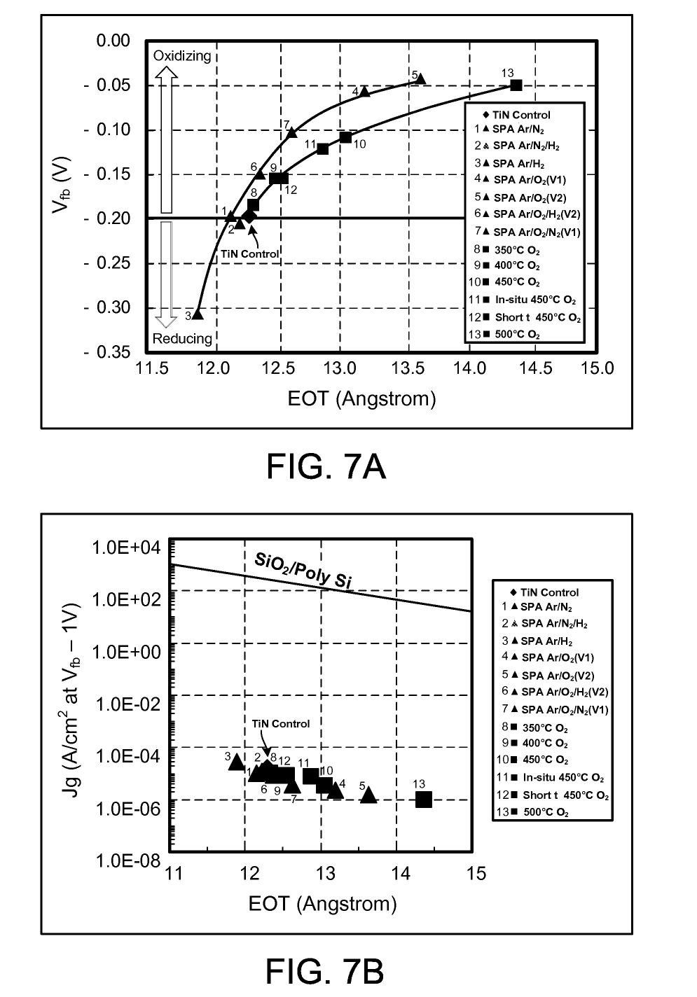

FIG. 7A shows flat band voltage (V_{fb}) as a function of equivalent oxide thickness (EOT) for modified titanium nitride (TiN) gate electrode films. The film test structures included Si substrate/chemical oxide (SiO₂)/HfO₂ film/TiN film. Following the modification of the TiN film, a metal cap layer was deposited on the modified TiN film and the resulting film structures were analyzed. The TiN gate electrode films were modified using microwave plasma process recipes 1)-7) at 250° C. for 90 seconds, thermal (non-plasma) process recipes 8-11 and 13 were performed for 300 seconds, and thermal (non-plasma) process recipe 12 was performed for 90 seconds. The microwave plasma process recipes included plasma formation using a microwave plasma source, such as a radial line slot antenna (RLSA) or a slotted plane antenna (SPA). The process recipes included: 1) Ar+N₂ plasma, 2) Ar+N₂+H₂ plasma, 3) Ar+H₂ plasma, 4) Ar+O₂ plasma, 5) Ar+O₂ plasma, 6) Ar+O₂+H₂, 7) Ar+O₂+N₂ plasma, 8) O₂ exposure at 350° C., 9) O₂ exposure at 400° C., 10) O₂ exposure at 450° C., 11) in-situ O₂ exposure at 450° C., 12) short O₂ exposure at 450° C., and 13) O₂ exposure at 500° C. Process recipe 11 was performed without an air break between the modification of the TiN film and the subsequent metal cap layer deposition. The thermal process recipes 8)-13) and the microwave plasma process recipes 4)-7) exposed the TiN gate electrode films to oxidizing species, whereas microwave plasma process recipe 1) exposed the TiN gate electrode films to reducing species. The results in FIG. 7A were compared to an unmodified TiN gate electrode film and showed that thermal exposure to oxidizing species resulted in increased V_{fb} (P-shift) and increased EOT. In comparison, the microwave plasma exposure to oxidizing species resulted in less increases in EOT than the thermal exposure for same or similar increases in V_{fb}. Further, the microwave plasma exposure to reducing species reduced both the V_{fb} (N-shift) and the EOT. FIG. 7B shows leakage current (J_{g}) as a function of EOT for modified titanium nitride (TiN) gate electrode films. The process recipes were described above for FIG. 7A.

In summary, FIGS. 7A and 7B show that reducing and oxidizing microwave plasma process recipes are very effective for modifying the V_{fb} of TiN gate electrode films and providing smaller EOTs than thermal processes. The reducing and oxidizing microwave plasma process recipes can thus be used to effectively modify or tune the work function of those films and devices made therefrom.

FIG. 8 is a schematic diagram of a plasma processing system containing a radial line slot antenna (RLSA) microwave plasma source for modifying a metal-containing gate electrode film according to an embodiment of the invention. The plasma produced in the plasma processing system 515 is characterized by low electron temperature and high plasma density. The plasma processing system 515 can, for example, be a TRIAS™ SPA processing system from Tokyo Electron Limited, Akasaka, Japan. The plasma processing system 515 contains a plasma processing chamber 550 having an opening portion 551 in the upper portion of the plasma processing chamber 550 that is larger than a substrate 525. A cylindrical dielectric top plate 554 made, for example, of quartz, aluminum nitride or aluminum oxide is provided to cover the opening portion 551.

Gas lines 572 are located in the side wall of the upper portion of plasma processing chamber 550 below the top plate 554. In one example, the number of gas lines 572 can be 16 (only two of which are shown in FIG. 8). Alternatively, a different number of gas lines 572 can be used. The gas lines 572 can be circumferentially arranged in the plasma processing chamber 550, but this is not required for the invention. A process gas can be evenly and uniformly supplied into a plasma region 559 in plasma processing chamber 550 from the gas lines 572. A process gas containing H₂, N₂, O₂, Ar, or He, or a combination of two or more thereof, may be supplied by a gas source 520. Gas flow rates of H₂, N₂, O₂, Ar, or He can be less than 500 sccm (standard cubic centimeters per minute), less than 200 sccm, or less than 100 sccm. For example, a gas flow rate of H₂ can be less than 100 sccm, a gas flow rate of N₂ can be less than 200 sccm, a gas flow rate of O₂ can be less than 500 sccm, and a Ar+H₂ gas flow rate can be less than 2000 sccm. The gas pressure in the plasma processing chamber can be less than 100 mTorr (milli-Torr), less than 50 mTorr, less than 30 mTorr, or less than 20 mTorr, for example. Although not shown in FIG. 8, the process gas may also be provided into the plasma region 559 through the slot antenna 560.

In the plasma processing system 515, microwave power is provided to the plasma processing chamber 550 through the top plate 554 via a slot antenna 560 having a plurality of slots 560A. The slot antenna 560 faces the substrate 525 to be processed and the slot antenna 560 can be made from a metal plate, for example copper. In order to supply the microwave power to the slot antenna 560, a waveguide 563 is disposed on the top plate 554, where the waveguide 563 is connected to a microwave power supply 561 for generating electromagnetic wave at a microwave frequency of about 2.45 GHz, for example. The waveguide 563 contains a coaxial waveguide 563A with a lower end connected to the slot antenna 560, a coaxial waveguide 563B connected to the upper surface side of the circular (coaxial) waveguide 563A, and a coaxial waveguide converter 563C connected to the upper surface side of the coaxial waveguide 563B. Furthermore, a rectangular waveguide 563D is connected to the input of the coaxial waveguide converter 563C and an output for the microwave power supply 561.

Inside the coaxial waveguide 563B, an axial portion 562 (or inner conductor) of an electroconductive material is coaxially provided with the outer conductor, so that one end of the axial portion 562 is connected to the central (or nearly central) portion of the upper surface of slot antenna 560, and the other end of the axial portion 562 is connected to the upper surface of the coaxial waveguide 563B, thereby forming a coaxial structure. The microwave power can, for example, be between about 0.5 W/cm² (Watts per square centimeter) and about 4 W/cm². Alternatively, the microwave power can be between about 0.5 W/cm² and about 3 W/cm². The microwave irradiation may contain a microwave frequency of about 300 MHz (mega-Hertz) to about 10 GHz (giga-Hertz, for example about 2.45 GHz, and the plasma may contain an electron temperature of less than or equal to 5 eV (electron volt), including 1, 1.5, 2, 2.5, 3, 3.5, 4, 4.5 or 5 eV, or any combination thereof. In other examples, the electron temperature can be below 5 eV, below 4.5 eV, below 4 eV, or even below 3.5 eV. In some examples, the electron temperature can be between 1 and 1.5 eV, between 1.5 and 2 eV, between 2 and 2.5 eV, between 2.5 and 3 eV, between 3.0 and 3.5 eV, between 3.5 and 4.0 eV, or between 4.0 and 4.5 eV. The plasma may have a density of about 1×10¹¹/cm³ (per cubic centimeter) to about 1×10¹³/cm³, or higher.

In addition, in the plasma processing chamber 550, a substrate holder 552 is provided opposite the top plate 554 for supporting and heating a substrate 525 (e.g., a wafer). The substrate holder 552 contains a heater 557 to heat the substrate 525, where the heater 557 can be a resistive heater. Alternatively, the heater 557 may be a lamp heater or any other type of heater. Furthermore the plasma processing chamber 550 contains an exhaust line 553 connected to the bottom portion of the plasma processing chamber 550 and to a vacuum pump 555. The substrate holder 552 can be maintained at a temperature greater than 200° C., greater than 300° C., or greater than 400° C. In some examples, substrate holder 552 can be maintained at a temperature of about 250° C., for example.

The plasma processing system 515 further contains a substrate bias system 556 configured to bias the substrate holder 552 and the substrate 525 for generating a plasma and/or controlling energy of ions that are drawn to a substrate 525. The substrate bias system 556 includes a substrate power source configured couple power to the substrate holder 552. The substrate power source contains a RF generator and an impedance match network. The substrate power source is configured to couple power to the substrate holder 552 by energizing an electrode in the substrate holder 552. A typical frequency for the RF bias can range from about 0.1 MHz to about 100 MHz, and can be 13.56 MHz. In some examples, the RF bias can be less than 1 MHz, for example less than 0.8 MHz, less than 0.6 MHz, less than 0.4 MHz, or even less than 0.2 MHz. In one example, the RF bias can be about 0.4 MHz. Alternatively, RF power is applied to the electrode at multiple frequencies. The substrate bias system 556 is configured for supplying RF bias power can be between 0 W and 100 W, between 100 W and 200 W, between 200 W and 300 W, between 300 W and 400 W, or between 400 W and 500 W. RF bias systems for plasma processing are well known to those skilled in the art. Further, the substrate bias system 556 includes a DC voltage generator capable of supplying DC bias between −5 kV and +5 kV to the substrate holder 552.

The substrate bias system 556 is further configured to optionally provide pulsing of the RF bias power the pulsing frequency can be greater than 1 Hz, for example 2 Hz, 4 Hz, 6 Hz, 8 Hz, 10 Hz, 20 Hz, 30 Hz, 50 Hz, or greater. Exemplary RF bias power can be less than 100 W, less than 50 W, or less than 25 W, for example. It is noted that one skilled in the art will appreciate that the power levels of the substrate bias system 556 are related to the size of the substrate 525 being processed. For example, a 300 mm Si wafer requires greater power consumption than a 200 mm wafer during processing.

Still referring to FIG. 8, a controller 599 includes a microprocessor, a memory, and a digital I/O port capable of generating control voltages sufficient to communicate and activate inputs of the plasma processing system 515 as well as monitor outputs from the plasma processing system 515. Moreover, the controller 599 is coupled to and exchanges information with plasma processing chamber 550, the vacuum pump 555, the heater 557, the substrate bias system 556, and the microwave power supply 561. A program stored in the memory is utilized to control the aforementioned components of plasma processing system 515 according to a stored process recipe. One example of controller 599 is a UNIX-based workstation. Alternatively, the controller 599 can be implemented as a general-purpose computer, digital signal processing system, etc.

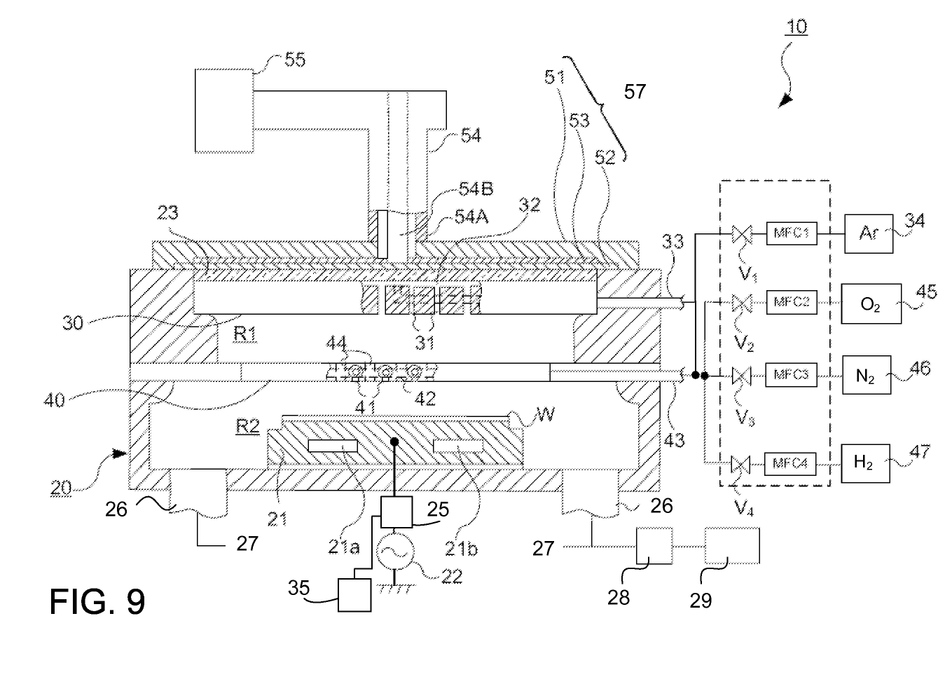

FIG. 9 is a schematic diagram of a another plasma processing system containing a radial line slot antenna (RLSA) microwave plasma source for modifying a metal-containing gate electrode film according to an embodiment of the invention. As shown in this figure, plasma processing system 10 includes a plasma processing chamber 20 (vacuum chamber), an antenna unit 57 (RLSA), and a substrate holder 21. The interior of the plasma processing chamber 20 is roughly sectionalized into a plasma generation region R1, located below a plasma gas supply unit 30, and a plasma diffusion region R2 at the substrate holder 21 side. The plasma generated in the plasma generation region R1 can have an electron temperature of several electron volts (eV). When the plasma is diffused into the plasma diffusion region R2, wherein the film formation process is performed, the electron temperature of the plasma near the substrate holder 21 drops to a value of lower than about 2 eV. The substrate holder 21 is located centrally on a bottom portion of the plasma processing chamber 20 and serves as a mounting unit for mounting a substrate W. Within the substrate holder 21, there is provided an insulating member 21a, a cooling jacket 21b, and a temperature control unit, not shown in this figure, for controlling the substrate temperature.

A top portion of the plasma processing chamber 20 is open-ended. The plasma gas supply unit 30 is placed opposite to the substrate holder 21 and is sealed with the top portion of the plasma processing chamber 20 via sealing members, not shown in this figure, such as O rings. The plasma gas supply unit 30, which may also function as a dielectric window, is made of materials such as aluminum oxide or quartz, and its planar surface, which has a virtual disk shape, faces the substrate holder 21. A plurality of gas supply holes 31 are provided opposite to the substrate holder 21 on the planar surface of the plasma gas supply unit 30. The plurality of gas supply holes 31 communicate with a plasma gas supply port 33 via a gas flow channel 32. A plasma gas supply source 34 provides plasma gas such as Ar gas, or other inert gases, into the plasma gas supply port 33. The plasma gas is then uniformly supplied into the plasma generation region R1 via the plurality of gas supply holes 31.

The plasma processing system 10 further includes a process gas supply unit 40, which is located substantially at the center of the plasma processing chamber 20 between the plasma generation region R1 and the plasma diffusion region R2. The process gas supply unit 40 is made of conducting materials such as aluminum alloy including magnesium (Mg) or stainless steel. Similar to the plasma gas supply unit 30, a plurality of gas supply holes 41 are provided on a planar surface of the process gas supply unit 40. The planar surface of the process gas supply unit 40 is positioned opposite to the substrate holder 21 and has a disk shape.

The plasma processing chamber 20 further includes exhaust lines 26 connected to the bottom portion of the plasma processing chamber 20, a vacuum line 27 connecting the exhaust line to a pressure controller valve 28 and to a vacuum pump 29. The pressure controller valve 28 may be used to achieve a desired gas pressure in the plasma processing chamber 20.

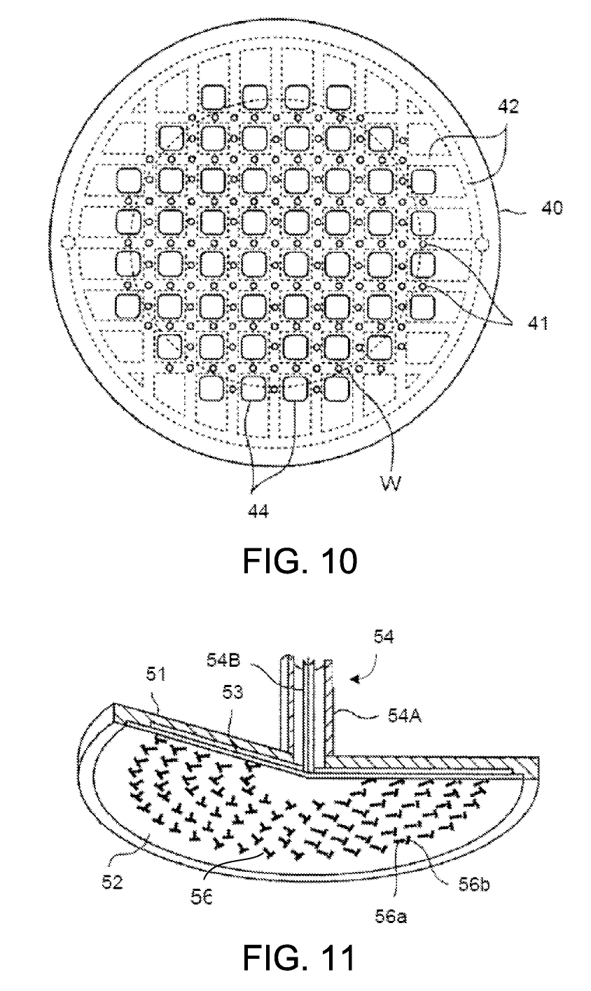

A plan view of the process gas supply unit 40 is shown in FIG. 10. As shown in this figure, a grid-like gas flow channel 42, also called a shower plate, is formed within the process gas supply unit 40. The grid-like gas flow channel 42 communicates with an upper-end of the plurality of gas supply holes 41, which are formed in the vertical direction. The lower end of the plurality of gas supply holes 41 are openings facing the substrate holder 21. The plurality of gas supply holes 41 communicate with a process gas supply port 43 via the grid-patterned gas flow channel 42.

Further, a plurality of openings 44 are formed on to the process gas supply unit 40 such that the plurality of openings 44 pass through the process gas supply unit 40 in vertical direction. The plurality of opening 44 passes the plasma gas, e.g., argon (Ar) gas, helium (He) gas, or other inert gases, into the plasma diffusion region R2 on the side of the substrate holder 21. As shown in FIG. 10, the plurality of openings 44 are formed between the adjacent gas flow channels 42. The process gas is supplied, for example, from separate process gas supply sources 45 and 46 to the process gas supply port 43. The process gas supply sources 45 and 46 can provide O₂ and N₂, respectively. A gas supply source 47 is provided for supplying H₂ gas. According to some embodiments, any combination of Ar (and/or He), H₂, O₂, and N₂ may be flowed through the process gas supply unit 40 and/or through the plasma gas supply port 33. Furthermore, for example, the plurality of openings 44 may occupy a region on the process gas supply unit 40 that extends beyond a peripheral edge of the substrate W.

The process gas flows through the grid-like gas flow channel 42 and are uniformly supplied into the plasma diffusion region R2 via the plurality of gas supply holes 41. The plasma processing system 10 further includes four valves (V1-V4) and four flow rate controller (MFC1-MFC4) for respectively controlling a supply of the gases into the plasma processing chamber 20.

An external microwave generator 55 provides a microwave signal (or microwave energy) of a predetermined frequency, e.g., 2.45 GHz, to the antenna unit 57 via a coaxial waveguide 54. The coaxial waveguide 54 may include an inner conductor 54B and an outer conductor 54A. The microwave from the microwave generator 55 generates an electric field just below the plasma gas supply unit 30, in the plasma generation region R1, which in turn causes excitation of the process gas within the plasma processing chamber 20.

FIG. 11 illustrates a partial cross-sectional view of the antenna unit 57. As shown in this figure, the antenna unit 57 may include a flat antenna main body 51, a radial line slot plate 52, and a dielectric plate 53 to shorten the wavelength of the microwave. The flat antenna main body 51 has a circular shape with an open-ended bottom surface. The radial line slot plate 52 is formed to close the open-ended bottom surface of the flat antenna main body 51. The flat antenna main body 51 and the radial line slot plate 52 are made of a conductive material with a flat hollowed circular shape waveguide.

A plurality of slots 56 is provided on the radial line slot plate 52 to generate a circular polarized wave. The plurality of slots 56 is arranged in a substantially T-shaped form having a slight gap there between, in a concentric circle pattern or a spiral pattern along a circumferential direction. Since the slots 56a and 56b are perpendicular to each other, a circular polarized wave containing two orthogonal polarized components is radiated, as a plane wave, from the radial line slot plate 52.

The dielectric plate 53 is made of a low loss dielectric material, e.g., aluminum oxide (Al₂O₃) or silicon nitride (Si₃N₄), which is located between the radial line slot plate 52 and the flat antenna main body 51. The radial line slot plate 52 is mounted on the plasma processing chamber 20 using sealing members (not shown), such that the radial line slot plate 52 is in close contact with a cover plate 23. The cover plate 23 is located on the upper surface of plasma gas supply unit 30 and is formed from a microwave transmissive dielectric material such as aluminum oxide (Al₂O₃).

An external high-frequency power supply source 22 is electrically connected to the substrate holder 21 via a matching network 25. The external high-frequency power supply source 22 generates an RF bias power of a predetermined frequency, e.g. 13.56 MHz, for controlling ions energy that are drawn to the substrate W. The power supply source 22 is further configured to optionally provide pulsing of the RF bias power the pulsing frequency can be greater than 1 Hz, for example 2 Hz, 4 Hz, 6 Hz, 8 Hz, 10 Hz, 20 Hz, 30 Hz, 50 Hz, or greater. The power supply source 22 is configured for supplying RF bias power can be between 0 W and 100 W, between 100 W and 200 W, between 200 W and 300 W, between 300 W and 400 W, or between 400 W and 500 W. It is noted that one skilled in the art will appreciate that the power levels of the power supply source 22 are related to the size of the substrate being processed. For example, a 300 mm Si wafer requires greater power consumption than a 200 mm wafer during processing. The plasma processing system 10 further includes DC voltage generator 35 capable of supplying DC voltage bias between about −5 kV and about +5 kV to the substrate holder 21.

During the modification of a metal-containing gate electrode film, the plasma gas, e.g., Ar gas, may be introduced into the plasma processing chamber 20 using the plasma gas supply unit 30. On the other hand, the process gas may be introduced into the plasma processing chamber 20 using the process gas supply unit 40.

A plurality of embodiments for modifying metal-containing gate electrode films for semiconductor devices using a microwave plasma source have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. For example, the term “on” as used herein (including in the claims) does not require that a film “on” a substrate is directly on and in immediate contact with the substrate; there may be a second film or other structure between the film and the substrate.

It should be understood that various modifications and variations of the present invention may be employed in practicing the invention. It is therefore to be understood that, within the scope of the appended claims, the invention may be practiced otherwise than as specifically described herein.

What is claimed is:

1. A method for forming a semiconductor device, comprising:
providing in a process chamber a metal-containing gate electrode film on a substrate;
flowing a process gas consisting of hydrogen (H₂) and optionally a noble gas into the process chamber;
forming plasma excited species from the process gas by a microwave plasma source; and
exposing the metal-containing gate electrode film to the plasma excited species to form a modified metal-containing gate electrode film having a lower work function than the metal-containing gate electrode film.

2. The method of claim 1, wherein the metal-containing gate electrode film comprises W, WN, Al, Mo, Ta, TaN, TaSiN, HfN, HfSiN, Ti, TiN, TiSiN, Mo, MoN, Nb, Re, Ru, or RuO₂.

3. The method of claim 1, wherein the semiconductor device further comprises a dielectric layer between the metal-containing gate electrode film and the substrate.

4. A method for forming a semiconductor device, comprising:
providing in a process chamber a metal-containing gate electrode film on a substrate;
forming first plasma excited species from a first process gas by a microwave plasma source; and
exposing the metal-containing gate electrode film to the first plasma excited species to form a first modified metal-containing gate electrode film and an unmodified metal-containing gate electrode film.

5. The method of claim 4, wherein the metal-containing gate electrode film comprises W, WN, Al, Mo, Ta, TaN, TaSiN, HfN, HfSiN, Ti, TiN, TiSiN, Mo, MoN, Nb, Re, Ru, or RuO₂.

6. The method of claim 4, wherein the first process gas consists of hydrogen (H₂) and optionally a noble gas, and wherein the first modified metal-containing gate electrode film has a lower work function than the unmodified metal-containing gate electrode film.

7. The method of claim 4, wherein the first process gas consists of oxygen (O₂) and optionally one or more gases selected from the group consisting of a noble gas, nitrogen (N₂), or H₂, or a combination thereof, and wherein the first modified metal-containing gate electrode film has a higher work function than the unmodified metal-containing gate electrode film.

8. The method of claim 4, wherein a first portion of the metal-containing gate electrode film is exposed to the first plasma excited species through an opening in a first patterned film over the first portion of the metal-containing gate electrode film.

9. The method of claim 4, further comprising
patterning the first modified metal-containing gate electrode film to form a first metal-containing gate electrode; and
patterning the unmodified metal-containing film to form a second metal-containing gate electrode.

10. The method of claim 4, further comprising
forming second plasma excited species from a second process gas by the microwave plasma source; and
exposing the unmodified metal-containing gate electrode film to the second plasma excited species to form a second modified metal-containing gate electrode film.

11. The method of claim 10, wherein the unmodified metal-containing gate electrode film is exposed to the second plasma excited species through an opening in a second patterned film over the unmodified metal-containing gate electrode film.

12. The method of claim 10, wherein the first process gas consists of oxygen (O₂) and optionally one or more gases selected from the group consisting of a noble gas, nitrogen (N₂), or H₂, or a combination thereof, and the second process gas consists of hydrogen (H₂) and optionally a noble gas, and
wherein the second modified metal-containing gate electrode film has a lower work function than the first modified metal-containing gate electrode film.

13. The method of claim 10, wherein the first process gas consists of hydrogen (H₂) and optionally one or more gases selected from the group consisting of a noble gas, and the second process gas consists of oxygen (O₂) and optionally a noble gas, nitrogen (N₂), or H₂, or a combination thereof, and
wherein the second modified metal-containing gate electrode film has a higher work function than the first modified metal-containing gate electrode film.

14. The method of claim 10, further comprising
patterning the first modified metal-containing gate electrode film to form a first metal-containing gate electrode; and
patterning the second modified metal-containing film to form a second metal-containing gate electrode.

15. A method for forming a semiconductor device, comprising:
providing in a process chamber a titanium nitride (TiN) gate electrode film on a substrate;
forming first plasma excited species from a first process gas by a microwave plasma source; and
exposing the TiN gate electrode film to the first plasma excited species through an opening in a first patterned film over a first portion of the TiN gate electrode film to form a first modified TiN gate electrode film and an unmodified TiN gate electrode film.

16. The method of claim 15, wherein the first process gas consists of hydrogen (H₂) and optionally a noble gas, and wherein the first modified TiN gate electrode film has a lower work function than the unmodified TiN gate electrode film.

17. The method of claim 15, wherein the first process gas consists of oxygen (O₂) and optionally one or more gases selected from the group consisting of a noble gas, nitrogen (N₂), or H₂, or a combination thereof, and wherein the first modified TiN gate electrode film has a higher work function than the unmodified TiN film.

18. The method of claim 15, further comprising
forming second plasma excited species from a second process gas by the microwave plasma source; and
exposing the unmodified TiN gate electrode film to the second plasma excited species through an opening in a second patterned film over the unmodified TiN gate electrode film to form a second modified TiN gate electrode film.

19. The method of claim 18, wherein the first process gas consists of oxygen (O₂) and optionally one or more gases selected from the group consisting of a noble gas, nitrogen (N₂), or H₂, or a combination thereof, and the second process gas consists of hydrogen (H₂) and optionally a noble gas, and
wherein the second modified TiN gate electrode film has a lower work function than the first modified TiN gate electrode film.

20. The method of claim 18, wherein the first process gas consists of hydrogen (H₂) and optionally a noble gas, and the second process gas consists of oxygen (O₂) and optionally one or more gases selected from the group consisting of a noble gas, nitrogen (N₂), or H₂, or a combination thereof, and
wherein the second modified TiN gate electrode film has a higher work function than the first modified TiN gate electrode film.
